(19) United States
(12) Patent Application Publication
(10) Pub. No.: US 2025/0183239 A1
(43) Pub. Date: Jun. 5, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Yi-Min FU, Taichung City (TW); Chi-Ching HO, Taichung City (TW); Yu-Po WANG, Taichung City (TW)

(21) Appl. No.: 18/734,743

(22) Filed: Jun. 5, 2024

(30) Foreign Application Priority Data
Dec. 1, 2023 (TW) 112146890

(51) Int. Cl. H01L 25/16; H01L 21/56; H01L 23/00; H01L 23/04; H01L 23/31; H01L 23/498; H01L 23/538

(52) U.S. Cl. CPC H01L 25/16; H01L 21/563; H01L 23/04; H01L 23/3135; H01L 23/49827; H01L 23/49838; H01L 23/5381; H01L 24/13; H01L 24/16; H01L 24/81; H01L 2224/13147; H01L 2224/16145; H01L 2224/16227; H01L 2224/81193; H01L 2924/1431; H01L 2924/1436

(57) ABSTRACT

An electronic package and a manufacturing method thereof are provided, in which a passive element and an interposer structure are disposed on a carrier structure, the passive element is encapsulated by an encapsulation layer, and the electronic element is disposed on and electrically connected to the passive element and the interposer structure. Therefore, by the design of the electronic element electrically connecting to the passive element, the power transmission path is shortened and the resistance is reduced, thereby achieving the effect of reducing power loss.

### CROSS-REFERENCE TO RELATED APPLICATIONS

The present application is based upon and claims the right of priority to TW patent application No. 112146890, filed Dec. 1, 2023, the disclosure of which is hereby incorporated by reference herein in its entirety for all purposes.

### BACKGROUND

### 1. Technical Field

The present disclosure relates to a semiconductor device, and more particularly, to an electronic package and a manufacturing method thereof.

### 2. Description of Related Art

With the vigorous development of the electronics industry, electronic products are gradually being developed toward the trend of multi-function and high performance, wherein the technologies used in the field of chip packaging include flip-chip packaging module such as chip scale package (CSP), direct chip attach (DCA) and multi-chip module (MCM), or chip stacking technology that stacks chips in three dimensions for integration into an integrated circuit.

FIG. 1 is a schematic cross-sectional view of a conventional chip-stacked semiconductor package 1, which comprises a through-silicon interposer (TSI) 11. The through-silicon interposer 11 has a plurality of conductive through-silicon vias (TSVs) 110 and a redistribution layer (RDL) 12, such that a semiconductor chip 16 is electrically bonded onto the conductive through-silicon vias 110 by a plurality of solder bumps 17. Then, the solder bumps 17 are covered with an underfill 160, and an encapsulant 18 is formed on the through-silicon interposer 11 and covers the semiconductor chip 16. The redistribution layer 12 is electrically bonded onto electrical contact pads 100 of a package substrate 10 via a plurality of conductors 14, and the conductors 14 are covered with an underfill 15.

In addition, when the assembly process of the semiconductor package 1 is subsequently applied, the semiconductor package 1 is bonded onto a circuit board (not shown) via the lower side of the package substrate 10, such that the conductive through-silicon vias 110 are used as the medium for signal transmission and power transmission between the semiconductor chip 16 and the circuit board.

However, in the conventional semiconductor package 1, a passive element 13 needs to be disposed on the package substrate 10 as a power transmission element, so that the power transmission path of the semiconductor package 1 needs to pass through the package substrate 10 and the through-silicon interposer 11 to reach to the semiconductor chip 16 from the passive element 13, resulting in a long power transmission path and extremely high resistance, thus causing the problem of excessive power loss.

Therefore, how to overcome the above-mentioned problems of the prior art has become an urgent issue to be solved.

### SUMMARY

In view of the various shortcomings of the prior art, the present disclosure provides an electronic package, which comprises: a carrier structure having a first electrical contact pad and a second electrical contact pad; at least one passive element disposed on the carrier structure and electrically connected to the first electrical contact pad; an interposer structure disposed on the carrier structure and electrically connected to the second electrical contact pad; and an electronic element disposed on and electrically connected to the passive element and the interposer structure.

The present disclosure also provides a method of manufacturing an electronic package, the method comprises: providing a carrier structure having a first electrical contact pad and a second electrical contact pad; disposing a passive element and an interposer structure on the carrier structure, wherein the passive element is electrically connected to the first electrical contact pad, and the interposer structure is electrically connected to the second electrical contact pad; and disposing an electronic element on the passive element and the interposer structure, wherein the electronic element is electrically connected to the passive element and the interposer structure.

In the aforementioned electronic package and method, the carrier structure is formed with a recess accommodating the passive element.

In the aforementioned electronic package and method, a plurality of the passive elements are disposed on the carrier structure.

In the aforementioned electronic package and method, the passive element has a first contact and a second contact opposing the first contact, wherein the first contact is electrically connected to the first electrical contact pad, and the second contact is electrically connected to the electronic element.

In the aforementioned electronic package and method, the interposer structure comprises a plate body having a plurality of penetrating conductive vias, wherein the conductive via is electrically connected to the electronic element and the second electrical contact pad. For example, the interposer structure further comprises a circuit portion bonded to the plate body, wherein the conductive via is electrically connected to the second electrical contact pad via the circuit portion. Or, the interposer structure is disposed on the second electrical contact pad via a conductor.

In the aforementioned electronic package and method, a plurality of the electronic elements are disposed on the interposer structure, and the interposer structure electrically bridges at least two of the plurality of electronic elements.

In the aforementioned electronic package and method, the interposer structure is served as a signal transmission element for the electronic element.

In the aforementioned electronic package and method, the present disclosure further comprises encapsulating the passive element via an encapsulation layer.

It can be seen from the above that in the electronic package and manufacturing method thereof according to the present disclosure, the power transmission path of the electronic package is greatly shortened via the design of the electronic element being electrically connected to the passive element. Therefore, compared to the prior art, the resistance of the electronic package of the present disclosure can be significantly reduced, thereby achieving the effect of reducing power loss effectively.

### BRIEF DESCRIPTION OF THE DRAWINGS

FIG. 1 is a schematic cross-sectional view of a conventional semiconductor package.

FIG. 2A to FIG. 2E are schematic cross-sectional views illustrating a manufacturing method of an electronic package of the present disclosure.

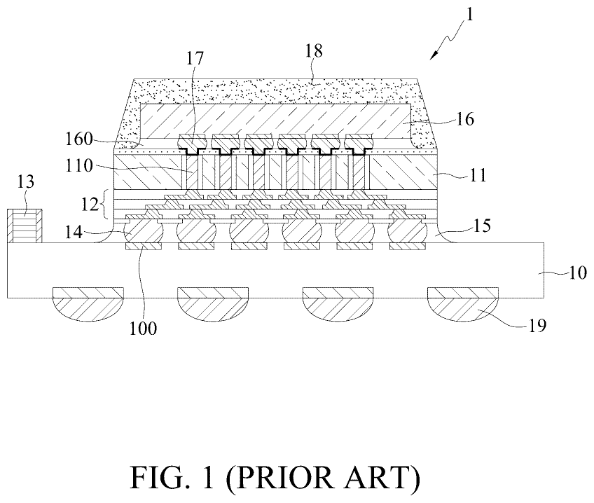

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” “one,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

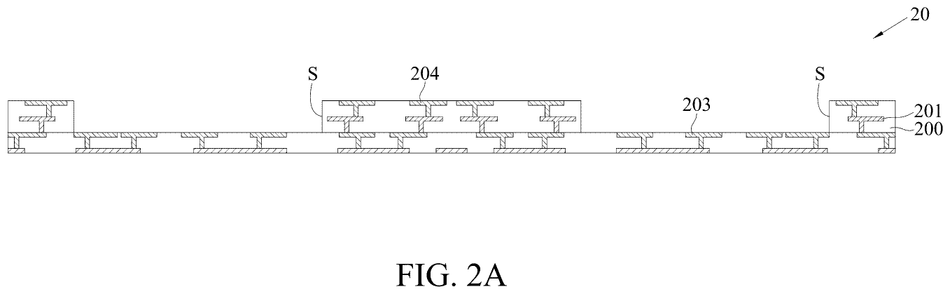

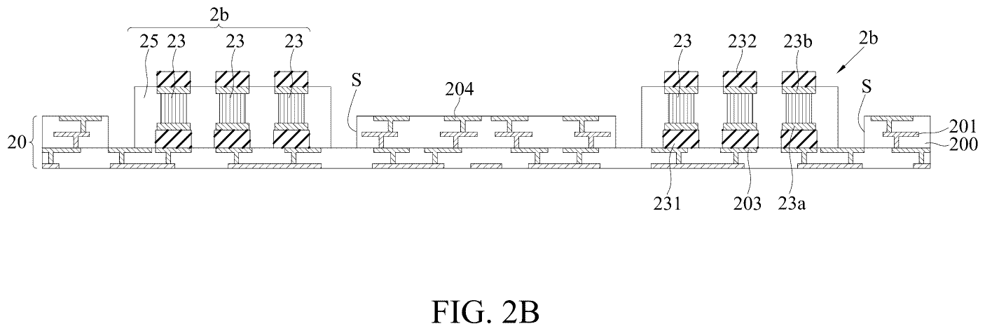

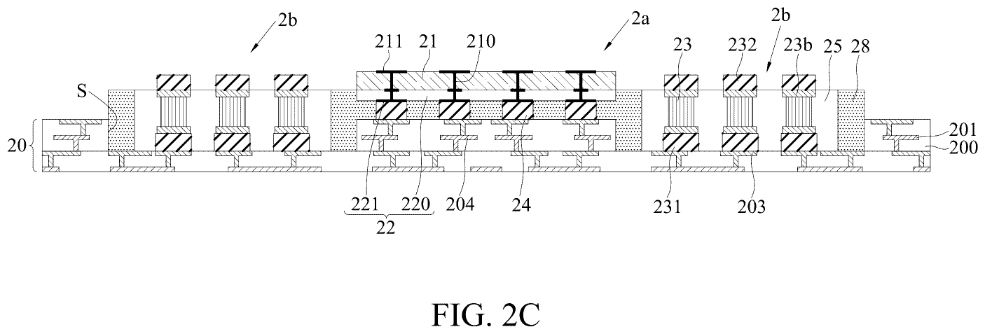

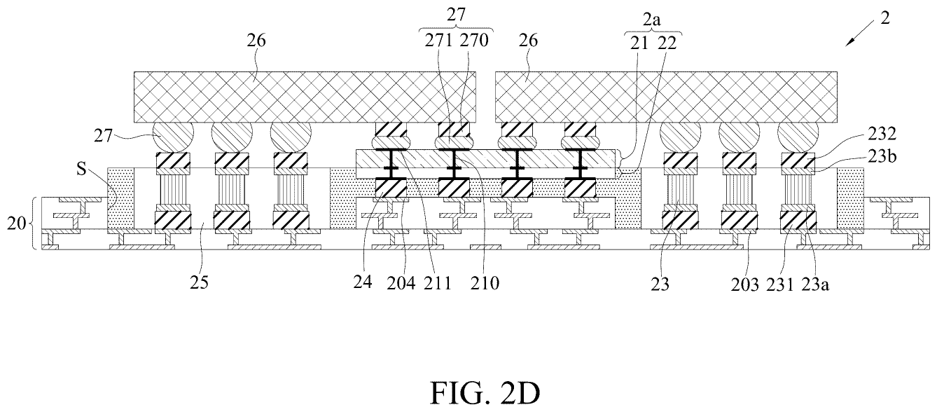

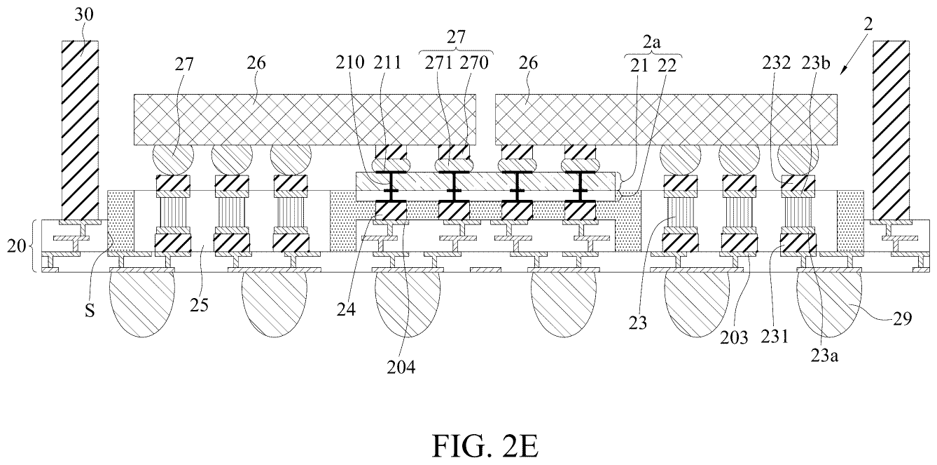

FIG. 2A to FIG. 2E are schematic cross-sectional views illustrating a manufacturing method of an electronic package 2 of the present disclosure.

As shown in FIG. 2A, a carrier structure 20 with at least one recess S (two recesses S are shown in the embodiment of FIG. 2A) is provided. The carrier structure 20 is for example a package substrate with a core layer, a coreless package substrate, or other types of routing structure.

In an embodiment, the carrier structure 20 is a coreless package substrate and has at least one insulation material 200 and at least one routing layer 201 bonded on the insulation material 200, such as of a redistribution layer (RDL) specification. For example, the insulation material 200 is dielectric material such as polybenzoxazole (PBO), polyimide (PI), prepreg (PP), or the like.

Moreover, part of the surface of the routing layer 201 is exposed from the bottom surface of the recess S and the surface of the carrier structure 20 to serve as first electrical contact pads 203 and second electrical contact pads 204.

As shown in FIG. 2B, at least one passive module 2b electrically connected to the routing layer 201 is accommodated in the recess S, wherein the passive module 2b comprises at least one passive element 23 electrically connected to the first electrical contact pad 203 and a cladding layer 25 encapsulating the passive element 23.

In an embodiment, the passive module 2b comprises a plurality of the passive elements 23 spaced apart from each other, and the passive elements 23 are resistors, capacitors and inductors. For example, the passive element 23 has a first contact 23a and a second contact 23b opposing the first contact 23a, such that the first contact 23a is electrically connected to the first electrical contact pad 203 via a conductive bump 231, and the second contact 23b is bonded to another conductive bump 232 and is exposed from the surface of the cladding layer 25. It can be understood that the conductive bumps 231, 232 may be metal bumps such as copper bumps or made of solder material, and the present disclosure is not limited to as such.

Furthermore, the cladding layer 25 is made of insulation material, such as polyimide (PI), dry film, encapsulant such as epoxy (epoxy resin), or molding compound.

As shown in FIG. 2C, at least one interposer structure 2a is disposed on the carrier structure 20, and an encapsulation layer 28 is formed on the carrier structure 20, such that the encapsulation layer 28 encapsulates the passive modules 2b and part of the interposer structure 2a.

In an embodiment, the interposer structure 2a comprises a plate body 21 and a circuit portion 22 bonded to the plate body 21, wherein a plurality of penetrating conductive vias 210 are formed in the plate body 21, and the conductive vias 210 are made to form connection pads 211 on the surface of the plate body 21. For example, the plate body 21 is a semiconductor plate such as a silicon plate or a glass plate, and the conductive vias 210 are conductive through-silicon vias (TSVs).

In addition, the circuit portion 22 comprises at least one insulation layer 220 and a conductive trace 221 bonded to the insulation layer 220, such as of a redistribution layer (RDL) specification, so that the conductive trace 221 is electrically connected to the conductive via 210. For example, the insulation layer 220 is made of dielectric material such as polybenzoxazole (PBO), polyimide (PI), prepreg (PP), or the like.

Also, the circuit portion 22 of the interposer structure 2a is disposed on the carrier structure 20 via a plurality of conductors 24 and is electrically connected to the routing layer 201. For example, the conductive trace 221 is electrically connected to the second electrical contact pad 204 via the conductor 24. It can be understood that the conductors 24 may be metal bumps such as copper bumps or made of solder material, and the present disclosure is not limited to as such.

Moreover, the encapsulation layer 28 is made of insulation material, such as polyimide (PI), dry film, encapsulant such as epoxy (epoxy resin), or molding compound. For example, the encapsulation layer 28 may be formed on the carrier structure 20 by liquid compound, injection, lamination, or compression molding and encapsulates the circuit portion 22 of the interposer structure 2a and the conductors 24, and the conductive bumps 232 on the second contacts 23b of the passive elements 23 are exposed from the encapsulation layer 28. It can be understood that the material forming the encapsulation layer 28 may be the same as or different from the material of the cladding layer 25.

As shown in FIG. 2D, a plurality of electronic elements 26 are disposed on the passive modules 2b and the interposer structure 2a, such that the electronic elements 26 are electrically connected to the passive modules 2b and the interposer structure 2a.

In an embodiment, the electronic elements 26 are active elements, and the interposer structure 2a electrically bridges at least two of the electronic elements 26. For example, the electronic elements 26 are semiconductor chips such as graphics processing units (GPUs), high bandwidth memories (HBMs), etc.

Furthermore, the electronic elements 26 are electrically connected to the conductive bumps 232 of the passive modules 2b (the passive elements 23) and to the connection pads 211 of the conductive vias 210 of the interposer structure 2a in a flip-chip manner via a plurality of conductive elements 27. For example, the conductive elements 27 may be metal bumps 270 such as copper bumps and/or solder materials 271.

Also, the interposer structure 2a is served as a signal transmission element for the electronic element 26, and the passive module 2b (the passive element 23) is served as a power transmission element for the electronic element 26.

In addition, as shown in FIG. 2E, a ball placement process may be performed on the lower side of the carrier structure 20 to form a plurality of solder balls 29 so as to obtain the electronic package 2 of the present disclosure, such that the solder balls 29 on the lower side of the electronic package 2 can be disposed on a circuit board (not shown) in a subsequent process. Further, a strengthening member 30, such as a metal frame, may be disposed on the upper side of the carrier structure 20 as required so as to eliminate the problem of concentration of stress and prevent the carrier structure 20 from warping, and the strengthening member 30 may even provide heat dissipation for the carrier structure 20.

Therefore, in the manufacturing method of the present disclosure, the passive modules 2b (the passive elements 23) and the electronic elements 26 are electrically connected with each other via the configuration of the passive modules 2b (the passive elements 23) so as to greatly shorten the power transmission path of the electronic package 2, such that the resistance of the power transmission path of the electronic package 2 is greatly reduced. Thus, compared to the prior art, the electronic package 2 of the present disclosure can prevent the problem of excessive power loss, thereby achieving the effect of reducing power loss.

The present disclosure also provides an electronic package 2, which comprises: a carrier structure 20, at least one passive element 23, an interposer structure 2a, an encapsulation layer 28, and at least one electronic element 26.

The carrier structure 20 has a first electrical contact pad 203 and a second electrical contact pad 204.

The passive element 23 is disposed on the carrier structure 20 and electrically connected to the first electrical contact pad 203.

The interposer structure 2a is disposed on the carrier structure 20 and electrically connected to the second electrical contact pad 204.

The encapsulation layer 28 encapsulates the passive element 23.

The electronic element 26 is disposed on the passive element 23 and the interposer structure 2a and is electrically connected to the passive element 23 and the interposer structure 2a.

In an embodiment, the carrier structure 20 is formed with a recess S accommodating the passive element 23.

In an embodiment, a plurality of the passive elements 23 are disposed on the carrier structure 20.

In an embodiment, the passive element 23 has a first contact 23a and a second contact 23b opposing the first contact 23a, such that the first contact 23a is electrically connected to the first electrical contact pad 203, and the second contact 23b is electrically connected to the electronic element 26.

In an embodiment, the passive element 23 is served as a power transmission element for the electronic element 26.

In an embodiment, the interposer structure 2a comprises a plate body 21 having a plurality of penetrating conductive vias 210, such that the conductive via 210 is electrically connected to the electronic element 26 and the second electrical contact pad 204. For example, the interposer structure 2a further comprises a circuit portion 22 bonded to the plate body 21, such that the conductive via 210 is electrically connected to the second electrical contact pad 204 via the circuit portion 22. Or, the interposer structure 2a is disposed on the second electrical contact pad 204 via a conductor 24, and the encapsulation layer 28 is further formed between the carrier structure 20 and the interposer structure 2a and encapsulates the conductor 24.

In an embodiment, a plurality of the electronic elements 26 are disposed on the interposer structure 2a, such that the interposer structure 2a electrically bridges at least two of the plurality of electronic elements 26.

In an embodiment, the interposer structure 2a is served as a signal transmission element for the electronic element 26.

In summary, in the electronic package and the manufacturing method thereof of the present disclosure, the power transmission path of the electronic package is greatly shortened via the design of the passive element and the electronic element being electrically connected to each other, such that the resistance of the power transmission path of the electronic package is greatly reduced. Therefore, the electronic package of the present disclosure can prevent the problem of excessive power loss, thereby achieving the effect of reducing power loss.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a carrier structure having a first electrical contact pad and a second electrical contact pad;
a passive element disposed on the carrier structure and electrically connected to the first electrical contact pad;
an interposer structure disposed on the carrier structure and electrically connected to the second electrical contact pad; and
an electronic element disposed on and electrically connected to the passive element and the interposer structure.

2. The electronic package of claim 1, wherein the carrier structure is formed with a recess accommodating the passive element.

3. The electronic package of claim 1, wherein a plurality of the passive elements are disposed on the carrier structure.

4. The electronic package of claim 1, wherein the passive element has a first contact and a second contact opposing the first contact, wherein the first contact is electrically connected to the first electrical contact pad, and the second contact is electrically connected to the electronic element.

5. The electronic package of claim 1, wherein the passive element is served as a power transmission element for the electronic element.

6. The electronic package of claim 1, wherein the interposer structure comprises a plate body having a plurality of penetrating conductive vias, wherein the conductive via is electrically connected to the electronic element and the second electrical contact pad.

7. The electronic package of claim 6, wherein the interposer structure further comprises a circuit portion bonded to the plate body, wherein the conductive via is electrically connected to the second electrical contact pad via the circuit portion.

8. The electronic package of claim 6, wherein the interposer structure is disposed on the second electrical contact pad via a conductor.

9. The electronic package of claim 1, wherein a plurality of the electronic elements are disposed on the interposer structure, and the interposer structure electrically bridges at least two of the plurality of electronic elements.

10. The electronic package of claim 1, wherein the interposer structure is served as a signal transmission element for the electronic element.

11. The electronic package of claim 1, further comprising an encapsulation layer encapsulating the passive element.

12. A method of manufacturing an electronic package, comprising:
providing a carrier structure having a first electrical contact pad and a second electrical contact pad;
disposing a passive element and an interposer structure on the carrier structure, wherein the passive element is electrically connected to the first electrical contact pad, and the interposer structure is electrically connected to the second electrical contact pad; and
disposing an electronic element on the passive element and the interposer structure, wherein the electronic element is electrically connected to the passive element and the interposer structure.

13. The method of claim 12, wherein the carrier structure is formed with a recess accommodating the passive element.

14. The method of claim 12, wherein a plurality of the passive elements are disposed on the carrier structure.

15. The method of claim 12, wherein the passive element has a first contact and a second contact opposing the first contact, wherein the first contact is electrically connected to the first electrical contact pad, and the second contact is electrically connected to the electronic element.

16. The method of claim 12, wherein the passive element is served as a power transmission element for the electronic element.

17. The method of claim 12, wherein the interposer structure comprises a plate body having a plurality of penetrating conductive vias, wherein the conductive via is electrically connected to the electronic element and the second electrical contact pad.

18. The method of claim 17, wherein the interposer structure further comprises a circuit portion bonded to the plate body, wherein the conductive via is electrically connected to the second electrical contact pad via the circuit portion.

19. The method of claim 17, wherein the interposer structure is disposed on the second electrical contact pad via a conductor.

20. The method of claim 12, wherein a plurality of the electronic elements are disposed on the interposer structure, and the interposer structure electrically bridges at least two of the plurality of electronic elements.

21. The method of claim 12, wherein the interposer structure is served as a signal transmission element for the electronic element.

22. The method of claim 12, further comprising encapsulating the passive element via an encapsulation layer.
